(19) United States
(12) Patent Application Publication
(10) Pub. No.: US 2004/0208681 A1
(43) Pub. Date: Oct. 21, 2004

(54) Computer or input device with back side keyboard

(76) Inventor: Joseph Fernand Dechene, Nashua, NH (US)

Correspondence Address: Joseph Dechene, 37 Whitford Rd, Nashua, NH, 03062, US

(21) Appl. No.: 10/810,906

(22) Filed: Mar. 27, 2004

Related U.S. Application Data
(60) Provisional application No. 60/464,012, filed on Apr. 19, 2003.

(51) Int. Cl. H03M 11/00

(52) U.S. Cl. 400/472; 400/691

(57) ABSTRACT

A portable handheld computer or input device (FIG. 8) (10) that allows rapid data entry and better screen (12) (FIG. 13) real estate by putting the primary input keys (38), (40) on the back side. Recessed side areas (FIGS. 8, 13) (22), (24) and inserts (50), (52) allow easy positioning of the hands for automatic alignment to a “home row” set of back side keys (38), (40). Certain keys and other input can be put on the back side, such as a split QWERTY keyboard (38), (40) and mouse device, while other keys can be put on the front, such as a numeric keypad (16), cursor movement and control input (20), Shift, Space, Backspace, Enter keys (18) and special keys (14).

### CROSS-REFERENCE TO RELATED APPLICATIONS

This application claims the benefit of PPA Ser. No. 60/464,012, filed Apr. 19, 2003 by the present inventor.

### FEDERALLY SPONSORED RESEARCH

None.

### SEQUENCE LISTING

None.

### BACKGROUND OF THE INVENTION

1. Field of the Invention

This invention relates to portable computers and portable input devices where rapid data entry is necessary or desirable.

2. Background

Computers have evolved from mainframe to minicomputer to personal computer or workstation. Portable computers have similarly evolved, from transportable suitcase style computers to laptops to tablets to PDA (personal digital assistant.) The goal has been to pack the most computing power in the smallest package while allowing rapid data entry.

Portable laptop or notebook computers generally have full-sized or nearly full-sized keyboards that allow data entry. However such computers do not readily allow entry when the user is standing, in motion, or away from a table. Such devices are common today, and are described by U.S. Pat. No. 4,667,299 (Dunn, 1987), U.S. Pat. No. 4,509,138 (Hayashi, et al., 1985), and U.S. Pat. No. 4,497,036 (Dunn, 1985)

Tablets and PDA's allow data entry while the user is standing, in motion, or away from a table. However data entry is restricted by a user inputting data via stylus or small sized keyboard on the front surface of the unit. Stylus entry of data is much slower than by using a full size keyboard, particularly if the user has experience with a keyboard. Some tablet computers are convertible, allowing rapid keyboard entry while at a table, or portable slower data entry via the tablet stylus or other input device. FIG. 4 shows a convertible tablet and laptop computer. But the tablet computer as described does not allow simultaneous rapid data entry from a user standing or in motion. U.S. Pat. No. 5,200,913 (Hawkins, et al., 1993), U.S. Pat. No. 5,355,279 (Lee, et al., 1994), U.S. Pat. No. 5,333,116 (Hawkins, et al., 1994) highlights a similar concept. U.S. patent application 20010001859 (Hawkins, Jeff C., et al., 2001) illustrates another example.

Efforts to cross the line between portable computer and PDA include U.S. patent application 20030002007 (Meringer, James A., 2003) entail a front side keyboard split on the sides of a front side display. However the rapid input keys on the front side takes up front side real estate, in addition it is more difficult to simultaneously hold and input data while in motion than in the proposed invention.

Efforts have been made in making PDA's more effective at rapid data entry. Some PDA's come with tiny front side keyboards that allow quick entry of small amounts of data while the user is standing or in motion. Examples include U.S. Pat. No. 6,611,255 (Griffin et. al, 2003) and U.S. Pat. No. D479,233 (Griffin, 2003). FIG. 5 shows an example. U.S. patent applications 20020165005 (Travers, Paul; et al., 2002), 20020182923 (Li, Chin-Chen; et al., 2002), 20020190957 (Lee, Soon; et al., 2002), and 20030020691 (Pan, Jung-Chuan; et al., 2003) shows implementations of a detachable keyboard. Attachable keyboards allow the PDA to be more effective, but restrict the user to be at a table or similar work surface to use. While the keyboards are very effective and portable, they still have this restriction. Such keyboards may be tiered, folding, roll-up, or even a virtual keyboard projected on to the table. All of these solutions require the user to be at a desk or table. Examples include U.S. Pat. No. 5,187,644 (Crisan, 1993), U.S. Pat. No. 5,245,559 (Lapeyre, 1993), U.S. Pat. No. 5,626,428 (Miwa, 1997), U.S. Pat. No. 5,687,058 (Roylance, 1997), U.S. Pat. No. 5,733,056 (Meagher, 1998), U.S. Pat. No. 5,712,760 (Coulon, et al., 1998), and U.S. Pat. No. 6,168,331 (Vann, 2001) (see FIG. 1.) U.S. patent applications 20020054779 (Hsu, Chien-Shih; et al., 2002) and 20020070921 (Feldman, Stephen E., 2002) also are examples.

Some input devices have input buttons or elements on the sides, backsides, or underside. An example is a trigger on a game joystick. However these devices are not for data entry in the sense of a large amount of data, such as typed text input.

Specialized input devices, such as U.S. Pat. No. 5,757,354 (Kawamura, 1998) provide a portable keyboard, but do not readily allow operation while standing or in motion.

Hand-holdable input devices with a limited number of front side keys, such as U.S. Pat. No. 5,023,438 (Wakatsuki, et al., 1991), U.S. Pat. No. 5,065,003 (Wakatsuki, et al., 1991), U.S. Pat. No. 5,245,559 (Lapeyre, 1993), U.S. Pat. No. 5,332,322 (Gambaro, 1994), and U.S. Pat. No. 5,331,136 (Koenck, et al., 1994) do not allow rapid input of quantity data as this invention. Likewise U.S. patent applications 20020077161 (Eromaki, Marko, 2002), 20020140680 (Lu, Jin, 2002), 20030038821 (Kraft, Joshua Dickinson, 2003) combine the display and keyboard on the front side of the unit, but such unit is substantially different from the proposed invention. It also is less suitable for rapid input of quantity data while the user is away from a table. U.S. patent application 20020097227 (Chu, Frank Rui-Feng; et al. , 2002) has multipurpose front panel keys, but is less suitable for simultaneous holding and typing than the proposed invention. Furthermore, such an input apparatus is more difficult to learn than the preferred embodiment of the proposed invention.

While most keyboards have keys substantially on the same plane, there are a few prior art units with keys on substantially other planes. U.S. Pat. No. 5,426,449 (Danziger, 1995) is an example (see FIG. 6) where the text input keys are on the sides of a pyramid shaped base. The intentions set forward in this device is for ergonomic entry and a more natural hand positioning. The keys in Danziger's device are not on the back side, nor are there hand positioning handles as in my Back Side Keyboard (BSK) invention. Danziger's device is meant to be at a table or desk, whereas my BSK device can readily be used away from a table or desk. U.S. Pat. No. 5,160,919 (Mohler, et al., 1992) is another example of similar ergonomic text entry with keyboards on the sides of the device.

Other specialized input devices such as U.S. Pat. No. 6,107,988 (Phillipps, 2000) (FIG. 2) allow for simultaneous holding, typing, and viewing as the present invention. However the devices as described and claimed in U.S. Pat. No. 6,107,988 deal mainly about accommodating flexible displays than input keyboards. The devices described and claimed do not allow natural positioning of the hands in the most advantageous holding and inputting. Furthermore there are no positioning handles and contours as described in the present invention. The user's hands may not automatically and quickly line up on the home rows of keypads. The user would have to visually and manually line up their fingers on initial placement. Once the user does line up their hands and fingers, they may lose that proper orientation once they started typing. The hand rotations necessary to reach the corner keys (such as the letters B or N) would tend to make the hands wander off the proper home row keys as the user attempted to rapidly type in data. A user might have to continually monitor the position of their hands on the keypads, defeating the goal of rapid data entry. Next, U.S. Pat. No. 6,107,988 does not have provision for certain keys or buttons on the front side. Also a hinged device compromises on the display capabilities and may compromise durability or manufacturability.

Prior art devices involved a double sided keyboard, such as U.S. Pat. No. 6,038,313 (Collins, 2000) for a telephone, but only to provide the user option to use while a flap is open or closed, not for rapid input of quantity data.

Prior art devices, such as described in U.S. Pat. No. 4,005,388 (Morley, et al., 1977), U.S. Pat. No. 4,007,443 (Bromberg, et al., 1977), U.S. Pat. No. 5,067,103 (Lapeyre, 1991), U.S. Pat. No. 5,124,940 (Lapeyre, 1992), U.S. Pat. No. 5,202,817 (Koenck, et al., 1993), U.S. Pat. No. 5,530,619 (Koenck, et al., 1996), U.S. Pat. No. 5,793,604 (Koenck, et al., 1998) (FIG. 3), and U.S. Pat. No. 5,418,684 (Koenck, et al., 1995), have keys on sides other than the front side of the device, and allow user entry while the user is standing or in motion. But these devices do not have keys on the back side, nor are they designed for rapid input of quantity text data.

Other portable computer or input devices are held or worn by the user, such as U.S. Pat. No. 5,023,824 (Chadima, Jr., et al., 1991), and U.S. Pat. No. 5,514,861 (Swartz, et al., 1996), but are generally not as useful as the present invention for rapid input of quantity data. U.S. Pat. No. 5,241,488 (Chadima, Jr., et al., 1993), and U.S. Pat. No. 5,416,310 (Little, 1995) entails a wearable computer with a keyboard held in one hand while the other hand inputs the data. This method is not as fast as the current invention for text data, and necessitates wearing a garment to effectively operate the computer or input device. Likewise US Patent U.S. Pat. No. 5,488,575 (Danielson, et al., 1996) has limited front side keyboards less suitable than this invention for rapid input of quantity data. U.S. patent application 20020034063 (Miller, William B. JR., 2002) describes a keyboard device that is held between the hands, but differs substantially from the proposed invention. The devices described in that application has a different handhold arrangement than the natural arrangement of the proposed invention here. Also my BSK invention has handles and contours to position the hands, whereas the prior art device held between the hands does not have the handles and contours.

Specialized devices allow one hand input of quantity data, but such devices have much steeper learning curves than the current invention. Examples include U.S. Pat. No. 4,360,892 (Endfield, 1982), and U.S. Pat. No. 4,442,506 (Endfield, 1984) where specific combination of finger and thumb inputs represents each letter. U.S. patent application 20020175834 (Miller, Martin, 2002) is another example.

Finally there is U.S. patent application 20030193477 (Goodenough, Gary Lee, 2003). See FIG. 7 Goodenough's key placement is more like my BSK invention than U.S. Pat. No. 6,107,988 (Phillipps, 2000) described above. However there are substantial differences between Goodenough's submittal and mine.

Goodenough does not illustrate or specify the recessed handles or contours as described in my BSK invention. He only describes markings to align the index fingers. Markings are not sufficient to maintain proper hand position and alignment during use. If the user were to hold Goodenough's device in a non-horizontal position, the weight of the device would exert a constant downward force. This would cause the device to shimmy down during typing. This would remove the hands from the proper home-row placement. A user would have to constantly reposition his or her hands in actual operation. That would negate any virtue of touch typing or rapid data entry. In other words, there would be enough misaligning slippage as one attempts to simultaneously hold his device and rapidly type.

Goodenough also does not make a provision for the unavoidable hand rotation during typing. The hands have a dual role—to simultaneously hold the device and type. Goodenough's tubular hand-holds are conducive to holding, but not the rotation during reach of certain keys, such as B or N on the back side. The user would have to relax his or her hold on Goodenough's tubular hand-holds to reach these keys, leading to loss of hand alignment.

There are other differences. For example Goodenough specifies mechanical normally closed contact switches to determine the presence of hands, whereas my preferred embodiment uses less obtrusive sensors. He specifies a complex telescoping carrying handle and setscrew adjustment of the entire tubular frame, whereas I have proposed inserts in some of my embodiments. Whereas he has a relatively small display compared to the unit's overall size, the display in my preferred embodiment is relatively large compared to my overall device size. Ultimately the overall size and shape of his embodiments are quite different from my embodiments.

Finally, there is an important dimension where the hand attempts to hold the unit and reach the back side keys. This is the distance from the side edge of the unit to the center of the home row of back side keys. In my BSK invention this dimension was achieved by experimenting with and using my working BSK demonstration models. Goodenough's dimension is not specified but appears to be far greater than mine. His embodiments would have to be substantially different to allow the device to work.

### BACKGROUND OF INVENTION—OBJECTS AND ADVANTAGES

The Back Side Keyboard (BSK) allows a hand-held computer or input device rapid data entry even if the user is not at a desk or table.

This device allows quantity and rapid data input while the user is standing, in motion, or seated where a table is not readily available. This allows user of the computer or input device while the user is performing a related function such as evaluation, inspection, data entry, or designing. Such a device can be used while the user is standing, waiting, walking, at a meeting, or in motion. Such a device can be readily used on a bus, train, or plane, without the hassle of unfolding, setting up, or using a necessary stylus or other input device that can be lost or misplaced.

The handles and contours of the BSK allow quick hand placement on the proper home row keys during initial placement of the hands. The handles and contours also keep the user's hands oriented to the proper home row keys as the user types, even as the user's hands do slight rotations to reach various keys. This allows a user to rapidly input data without excessive concentration on hand positioning from the user.

The size and simplicity of this device makes it ideal for mobile applications. In its preferred embodiment, the BSK device is a one-piece and non-folding unit. A user can quickly and easily take such unit out of their bag and put it to immediate use, especially if the BSK computer or input device is equipped with a rapid power-up and boot-up feature.

Further objects and advantages of my invention will become apparent from a consideration of the drawings and ensuing description.

### SUMMARY

A hand-holdable computer or input device with input keys on the back side as well as the front side of the unit. The device has side handles and contours which place the user's hands on the proper home rows of the back side keyboard. This allows a user to hold the device and rapidly input data even when not at a desk or a table.

### DRAWINGS

FIG. 8: Back Side of Invention—Vertically Aligned Keys.

The user's hands hold on to handles 22, 24, fingers reach around and naturally rest on the home row of keys 38, 40. Access to the other keys are facilitated by the vertical alignment of the keys which minimizes the hand rotation to reach other rows.

FIG. 9: Vertical Aligned Keyboard with Adjustment for Finger Reach.

An arrangement very similar to FIG. 8, but with adjustment in the positioning of the keys 38, 40 to allow better reach especially with the user's pinkie fingers.

FIG. 10: Back Side Keyboard with Accommodating Angle to Minimize Hand Movement.

Similar to FIG. 8, but with a slight angle of keys 38, 40 to fine tune each finger's natural motion in reaching the other rows of keys.

FIG. 11: Back Side of Invention—Split Keyboard of Original Geometry.

Handles and Inserts Assist in Aligning Hands to Minimize Hand Movement.

These keyboard halves 38, 40 have the same geometry as a conventional keyboard split. To accommodate the access to the other rows, the handle inserts 50, 52 have an overall slant to help. These handle inserts also have an overall curve to fit the hands to facilitate simultaneous hand holding and hand rotation during reach of the long reach keys such as B or N.

FIG. 12: Back Side Keyboard with Accommodating Angle to Minimize Hand Movement.

Similar to FIG. 10, but with inserts 50, 52. Notice that the overall angle of inserts is different from those shown in FIG. 11 to accommodate the different keyboard alignment angles. FIG. 12 also shows redundant keys 62 and back side pointing device 64.

FIG. 13: Front Side of Invention Showing Front Side Virtual Keys 14, 16, 18, 20 and Extended Display.

This is what the user sees on the display side. The user's hands grasp the handles 22, 24, with the fingers reaching the rapid input keys on the back side.

Front side buttons 14, 16, 18, 20 help with the control and special characters. In this illustration the display 12 is near full-width and the front-side keys 14, 16, 18, 20 are virtual and can be programmable.

FIG. 14: Front Side of Invention—Alternative Embodiment Front Side with Dedicated Keys and Dedicated Display.

Similar to FIG. 13, but with a smaller display 12 and dedicated front side keys 14, 16, 20. Many combinations are possible to the designer skilled in the art.

FIG. 15: Handle Insert Detail.

Shows the concept of inserts 50, (52) allowing the same device body 10 to accommodate different hand sizes and user preferences.

FIG. 16: Sculpted Handle to Allow Hand Rotation During Typing.

A handle 22 with curves to fit the natural curve of the hand. Facilitates simultaneous holding and hand rotation. As the hand rotates the curves allow the hands to effectively hold the device body securely. Similarly inserts 50, 52 can be curved also.

FIG. 17: Side View Handle Sensor Prevents Unintended Key Strokes.

The user's hands naturally reach around and rest on the home row of keys 3 8, (40). If the user has to let go with one hand, say to open a door, sensors 34 (and a corresponding sensor on the other handle) prevent unintended key entry as the other hand grips the body 10 tighter to hold it.

FIG. 18: Other Computer Functions Are Part of the Product as Needed. Edge view example.

Emphasizes the fact that the invention can represent a real computer able to do the job that laptops, tablets, and PDA's can do. And do it while the user is standing or in motion.

FIG. 19: Alternative Embodiment of Invention with Single Row of Back Side Keys and Shifters to Select Rows.

The alternative embodiment minimizes hand and finger motion by adding additional functions to the back row of keys 58, 60. Thumb selectors 54, 56 enable the each of the back side keys 58, 60 to represent several letters or characters or functions.

### Reference Numerals

10 Body of computer or input device

12 Display screen (for a computer)

14 Front side right hand input buttons or keys

16 Front side left hand input buttons or keys

18 Front side right hand text or input control

20 Front side left hand input control

22 Right side handle

24 Left side handle

26 Right side top guide contour

28 Right side bottom guide contour

30 Left side top guide contour

32 Left side bottom guide contour

34 Right side hand sensor

36 Left side hand sensor

38 Back side right hand keys

40 Back side left hand keys

42 Power switch

44 Auxiliary computer controls

46 Other computer function DVD drive

47 Other computer function wireless networking

48 Front side relief

50 Insert right side

52 Insert left side

54 Right Hand Row Selectors for Alternative Single Row Embodiment

56 Left Hand Row Selectors for Alternative Single Row Embodiment

58 Back side right hand keys on alternative embodiment

60 Back side left hand keys on alternative embodiment

62 Redundant reach character keys

64 Back side pointing device

### DETAILED DESCRIPTION

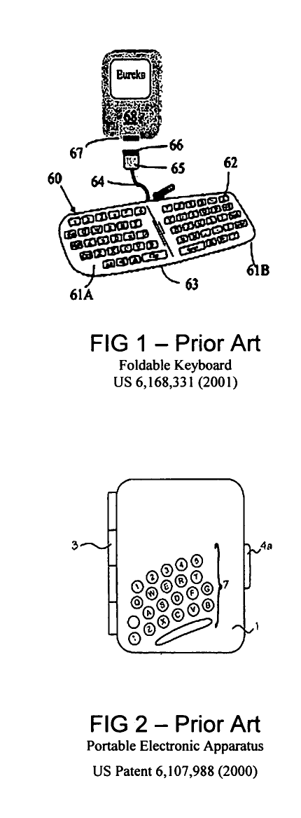

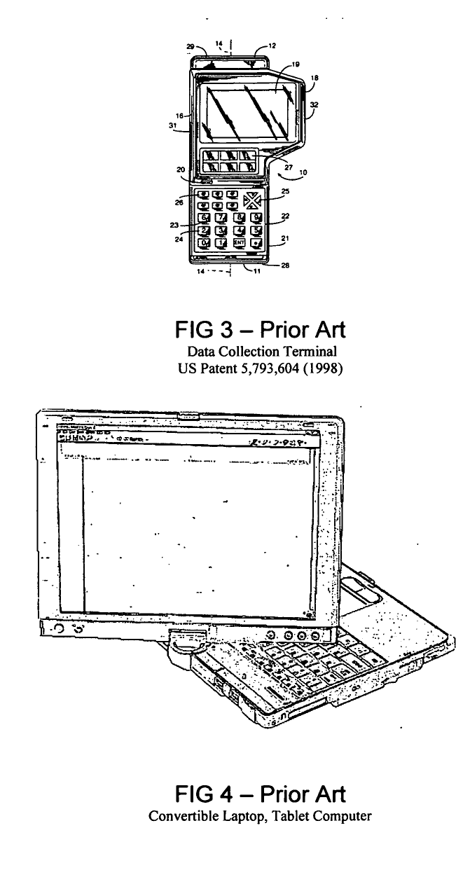

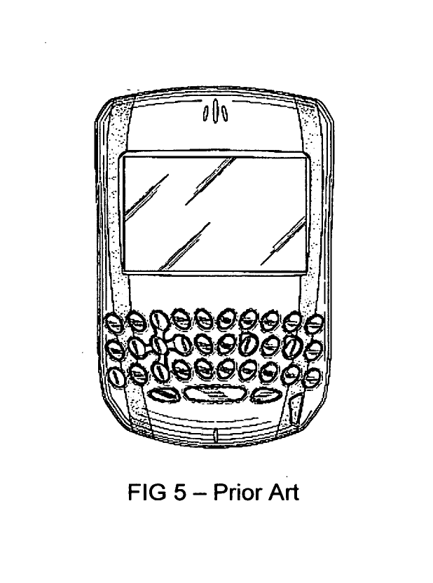

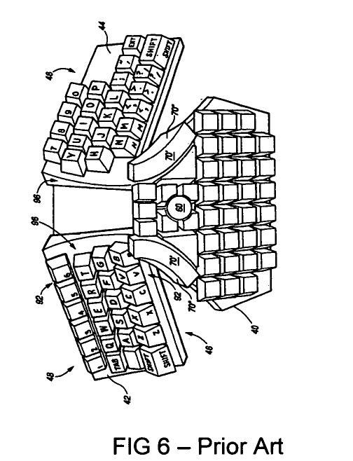

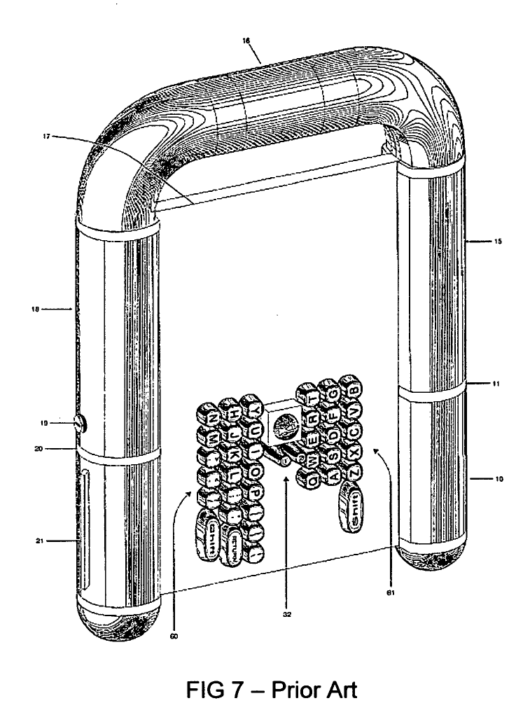

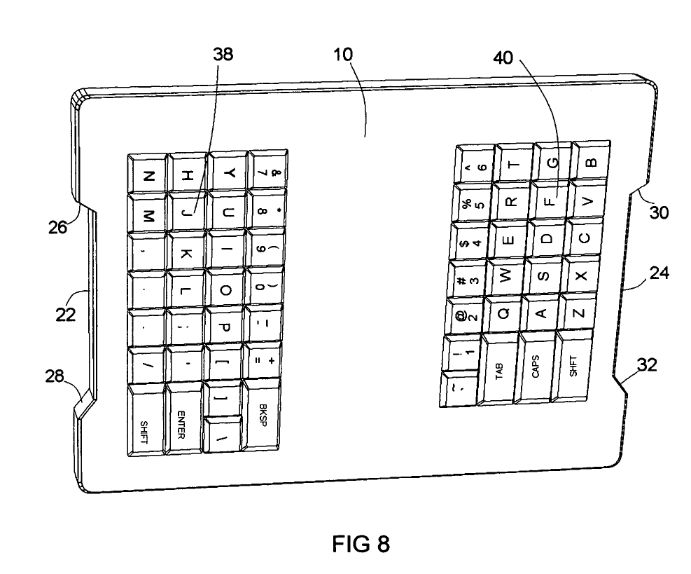

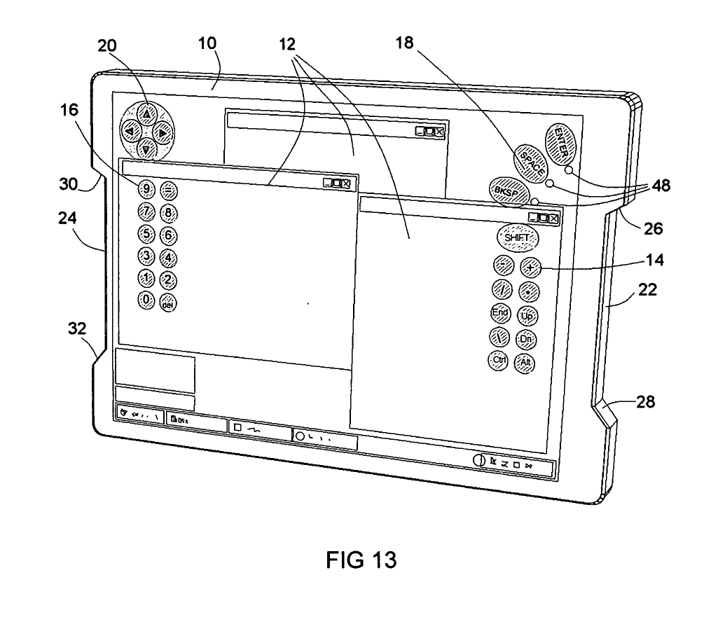

A preferred embodiment of the Back Side Keyboard (BSK) is illustrated in FIG. 8 (back side) and FIG. 13 (front side).

A computer or input device body 10 having a display 12 and front side input buttons or keys 14, 16. Keys 14 are for the right hand while keys 16 are for the left hand. In addition to the front side keys or buttons, there can be cursor, mouse, or input control keys 18, 20 on the front side by use of front side input control for the right hand and left hand.

In normal use, the user's hands hold or rest on the side handles 22, 24. The user's right hand holds handle 22 and the user's left hand holds handle 24. These side handles 22, 24 appear recessed due to the presence of contours or guides 26,28,30,32. When the user holds the device 10 in this manner, the user's fingers and thumbs are available for typing or data entry.

In normal use of the BSK computer or input device, the hands holding the handles 22, 24 naturally fit and position themselves between the contours 26, 28, 30, 32. With the hands in this position, the fingers normally reach around to the back side keyboards 38, 40. The handles 22, 24 and guides 26, 28, 30, 32 allow the fingers to naturally line up on the same set of keys repetitively and reliably. In the preferred embodiment, the user's hands rest against the top contours 26, 30, automatically lining up the user's fingers on the QWERTY home row, with the index fingers naturally lining up with the F and the J keys for the left and right hands respectively. On QWERTY keyboard pairs 38, 40 in the preferred embodiment in FIG. 8, the home row keys are a, s, d, f of back side keys 40 for the user's left hand, and home keys j, k, l, ; of back side keys 38 for the user's right hand

For example, the fingers line up on the home row positions of a QWERTY keyboard. This allows quick setup and accurate placement of the hands and fingers for immediate and rapid reliable data entry to the BSK computer or input device.

The natural placement of the hands, coupled with the combination of placement and BSK handles 22, 24 and contours 26,28,30,32, allows the user to use the BSK computer or input device to work while on the move, standing, riding, or other situations where it is impractical to use a laptop, tablet, or PDA. Even if the user is standing while operating this BSK computer in a vertical position, the top contours 26, 30 would rest against the outside index finger edges of the user's hands. The BSK and hands would maintain their relative alignment even as the user touch typed on the back side keyboard pairs 38, 40.

By having suitable rapid data entry keys on the back side 38, 40, coupled with the handles 22, 24 and contours 26,28,30,32, the user can naturally hold the device body 10 and rapidly input data. The user can rapidly input data in the standing or sitting position, even when not at a table. This is not possible with the prior art such as a notebook or tablet computer. The user can enter data while looking at the display 12, or while looking up, such as inventory control where the user may be looking at shelves of inventory while quickly typing in the required data into the BSK. For an input device, the user can look at a host computer screen while effortlessly rapidly inputting data into a BSK format input device.

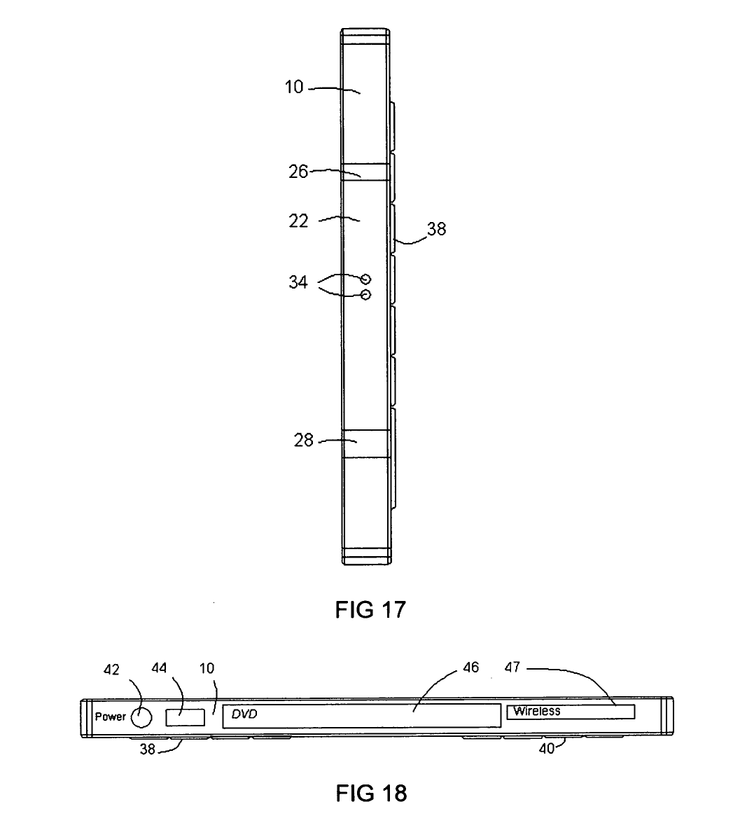

During moments when a user has to remove a hand from the BSK, the other hand will still be on the back side keys 38, 40 and the grip of the remaining hand would otherwise depress the corresponding back side keys 38 or 40. Sensors 34, 36 in the handles 22, 24 prevent the inadvertent input of false data in this circumstance by allowing input from the back side keys 38, 40 only when the user's hands are on each handle 22, 24. FIG. 17 shows the sensor detail, in this case right side sensors 34. Left side sensor 36 would be in the mirror position on the corresponding left handle 24.

Other functions would round out the operation of this device as needed for the particular or general application. These would include controls, I/O (possibly including a stylus input function), and computer specific functions, such as memory, disk (fixed and/or removable), connectivity (wireless and/or wired), and battery. FIG. 18 shows a possible arrangement of other functions, showing power switch 42 mounted on the top side of body 10. DVD drive 46 and wireless networking function 47 are illustrated in FIG. 18. In addition the back side can have a pointing device much in the same way that today's computers have a pointing device embedded in the keyboard.

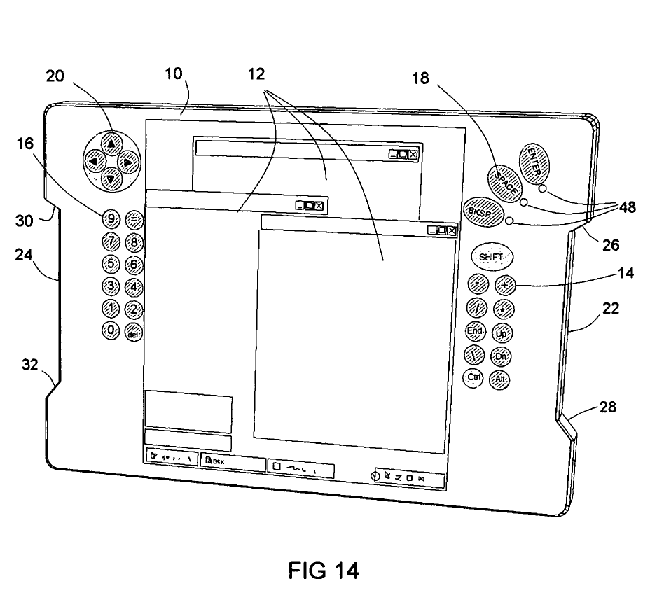

The front side of the device can have additional keys, buttons, touch-screen, or soft keys 14, 16. FIG. 13 and FIG. 14 show examples. In addition the front side can have mouse or cursor control function 20 and text control keys 18. These keys may have texture or other features to allow the user to navigate without looking down at the device while inputting data. This allows rapid data entry. In addition, front surface relief or features 48 can provide a sense of position for the front panel thumbs allowing location of the front input keys 14, 16. Relief can be on the screen by etching or other means even if the keys are soft or programmable or virtual keys. The shape of the relief 48 may be any means to provide sufficient tactile feedback: from small dimples to full outlines of the keys in question. On a virtual touch screen, small features 48 would minimize any effect on the display. FIG. 13 shows an example of virtual front side keys on a large display screen, while FIG. 14 shows permanent keys and a smaller display screen.

In the preferred embodiment shown in FIG. 13 the front keys 18 on the right hand side are readily accessed with the user's right thumb. These include the Enter, Space, Backspace, and Shift keys. In addition, there are +, −, /, *, end, up, \, down, control, and alt keys 14 arranged in the right side in two columns. Left front keys include directional arrows 20, numerals 0 to 9, decimal point (which is also the delete key), and equal keys 16. While the preferred embodiment has this front key arrangement, many other arrangements are possible. In fact it is possible to not have any front keys at all and rely on the back side keys 38, 40 only.

Although the dimensions shown in the preferred embodiment are 204 mm high by 280 mm wide, any set of dimensions can be used as long as there is room for a keyboard on the back side. Such a keyboard can be a full-sized 19 mm pitch or a smaller more compact size. The only requirement is that the dimensions should be sufficient to allow the hands to hold the device 10 and also input data.

The key to rapid data entry is to accommodate the hands to comfortably hold the BSK device 10 and automatically and naturally have the hands rest on the correct home key rows and key positions in back side keys 38 and 40. If the user can pick up the BSK device 10 and their hands naturally rest on the correct home row keys in 38 and 40, then the user can type instinctively if they are familiar with rapid data entry on a regular keyboard. In this case the “learning curve” is rapid. The handles 22, 24 and contours 26, 30 are key to allowing the natural holding and typing.

Certain dimensions are important to allow the hands to naturally hold and type at the same time at a rapid rate. These dimensions are as follows:

The side handles 22, 24 need to be wide enough to accommodate the user's hands comfortably.

The top contours 26, 30 need to be aligned such that the user's hands, when resting against these contours, allow the user's index fingers to line up with the letters F and J on the QWERTY keyboard.

The shape and positioning of these top contours 26, 30 provide the interface between device 10 alignment to the user's hands. While many specific embodiments are possible, generally a more pronounced top contour pair 26, 30 will readily allow the proper hand positioning. When the device is held as a vertical screen surface, the contours will provide a nearly horizontal surface to rest on the hands. This will allow the weight of the device to settle on the user's hands at the proper home row keyboard placement.

The setback of the back side keyboard should allow the user's hands when holding and typing, allow the fingers to naturally rest on the home row keys. This is about 50 mm from the home row (e.g. letters F and J) of back side keyboard halves 38, 40 to the outside edges of the handles 22, 24 or the inserts 50 on the back side.

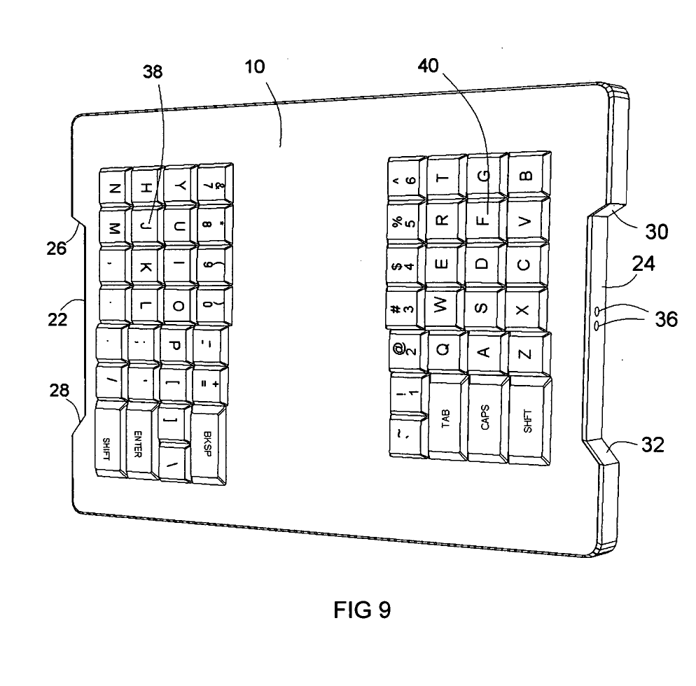

This dimension can vary, by putting the lower portion of the keyboard edges closer to the handle sides 22, 24 by angling the sides or by slanting the keyboard halves 38, 40. This allows the pinkie finger better access to its keys on each side. This can be accomplished by slanting the rows of the keys in FIG. 8 to allow easier pinkie finger reach. This can also be accomplished by slightly staggering the keys as shown in FIG. 9.

With this positioning, the hands are able to reach the home row naturally, while easily reaching the other rows without excessive motion.

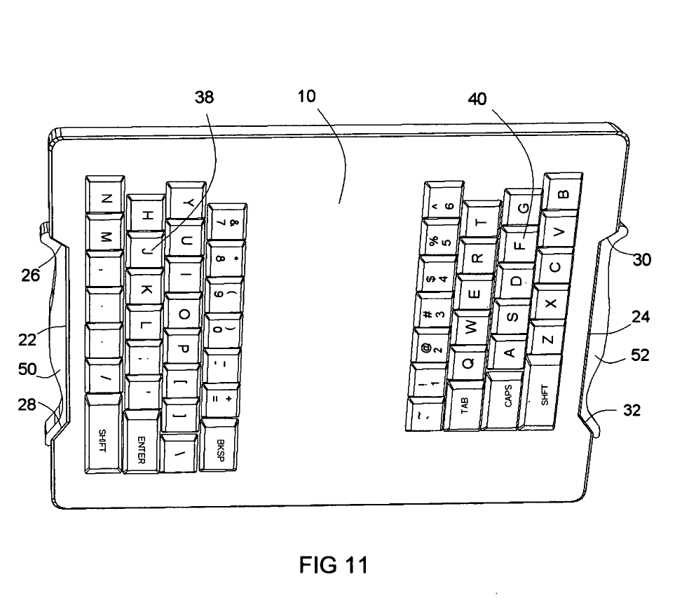

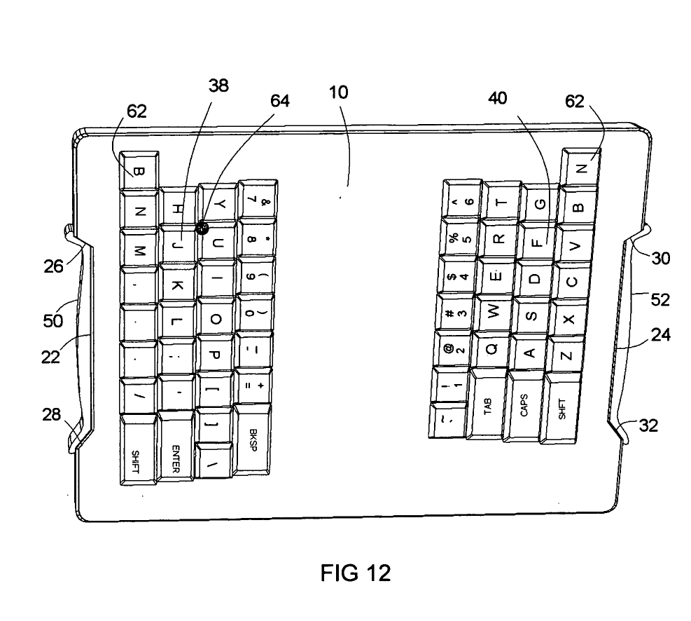

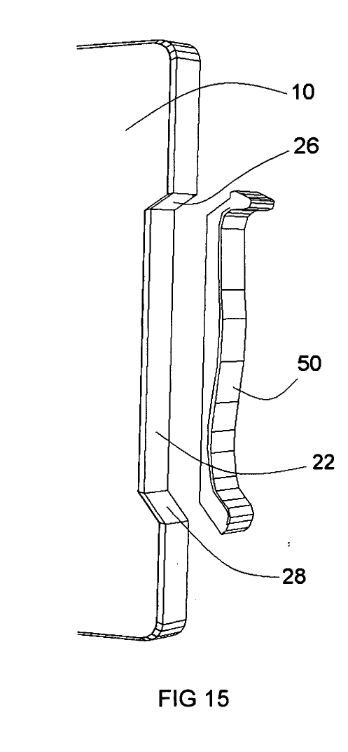

Larger hands will need more distance while smaller hands will need less. This can be accommodated by providing different size inserts 50, 52 (shown in FIG. 11 and FIG. 12, insert 50 is highlighted in FIG. 15) for the handles or other means. Inserts 50, 52 should preserve the same features of handles 22, 24 and contours 26, 28, 30, 32 to facilitate automatic hand alignment to the home set of keys. Specifically inserts 50, 52 should have the guides and contours similarly to handle contours 26,28,30,32.

Such inserts, needless to say, should be transparent to the sensors 34, 36. This can be accomplished by having a clear path for optical sensors, or a conductive path for resistive or capacitive sensors.

The position of the arms and hands on this device are different from a conventional keyboard. On a conventional keyboard, the position of the user's hands are much closer together than the distance between the user's shoulders. Hence the user's arms form a set of angles to position the hands on the keyboards. The alignment of the keys on a conventional keyboard are situated to allow a somewhat natural motion of the fingers as they go from the home row to the upper or lower rows.

The natural movement of the fingers on a back side keyboard device is a little different than on a regular keyboard. In normal use of a back side keyboard device, the user's fingers are naturally on the home row and the user's thumbs are on the upper front edges of the device. In this position, the fingers most easily travel in a nearly straight motion when reaching for other key rows. For example, the right index finger resting on the J key travels in a nearly straight motion to reach for the U key or down for the M key.

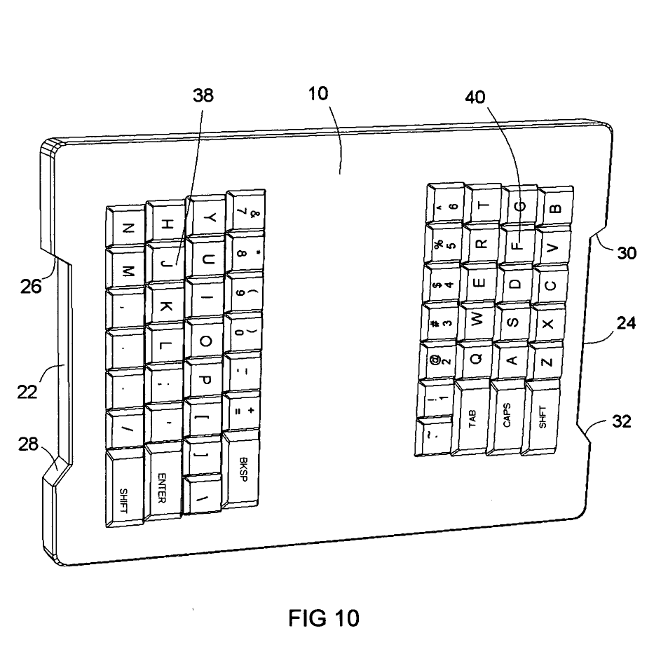

Therefore, on a back side keyboard, the keys can be aligned in a vertical arrangement as shown in FIG. 8. On the keyboard “vertical” refers to the columns of keys, e.g. input characters for M, J, U, and 8 on keyboard 38 in FIG. 8. In reality, experiments show that, given parallel handles 22, 24 the optimum angle is from vertical to a small angle going upwards toward the upper rows. FIG. 8 shows an arrangement with vertical alignment, while FIG. 10 and FIG. 12 show the slight angle of the keyboard 38, 40 as noted. Furthermore, the height of the keys can be varied to assist in natural placement.

The angle of the side handles 22, 24 on the front side and the alignment of the back side keys are related. For example if a conventional keyboard were split and placed on the back side, the angle of the handles 22, 24 would flare outwards slightly from the lower portion to the upper end. This would position the hands such that the natural motion of the fingers would follow the existing keyboard layout. Intermediate combinations are possible also. FIG. 11 shows a conventionally split keyboard 38, 40 being accommodated by inserts 50, 52 on each handle 22, 24. Note that the inserts 50, 52 in FIG. 11 have an overall slant outward to help position the hands correctly on the conventionally split keyboard. The different keyboard in FIG. 12 has inserts 50, 52 to accommodate proper finger and hand movement for that keyboard alignment.

The design of the side handles should have a means to allow the hands to slightly rotate while reaching the column of keys that are not on the home column. For example in FIG. 12 the reach characters B and N 62 force the appropriate hand to slightly rotate to access these letters. The above combination of back side keyboard alignment and handle placement minimizes the rotation of the hands in these circumstances. Especially when compared to the left hand movements necessary to access such keys on a conventional keyboard. However some rotation of the hands is still necessary.

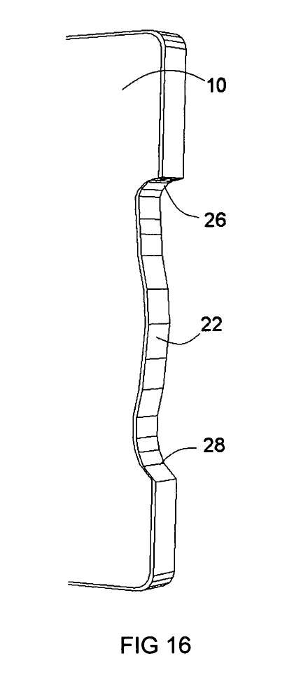

Rotation of the hands can be accomplished a variety of ways. The simplest way is to sculpt the handles 22, 24 or inserts 50, 52 with additional contours to fit the palms when suitably positioned on the handles. This allows the hand to rotate outward when accessing lower row keys with the index finger. For example the letters N and B. While the hand is rotated or lifted the contour still allows the hand to hold the overall device and still maintain position of the hand over the correct home row touch typing arrangement. Likewise the contours at the top portions of handles 22, 24 allow the pinkie fingers to access such keys CAPS, TAB, ], etc. by allowing the hand to rotate by lifting the lower portion of the hand while still maintaining suitable home row position. FIG. 16 shows a sculpted version of handle 22. FIG. 11 shows sculpted inserts 50, 52 to facilitate hand rotation. The inserts 50, 52 in FIG. 12 also show some curvature for facilitating hand rotation while holding and typing.

There are other ways of facilitating the hand rotation during reaching of off-column keys. Foam inserts 50 allow the hands to rotate while allowing sure contact with the handles. The flatter insert 50 shown in FIG. 15 could be made out of a compliant material such as foam to facilitate hand rotation. Insert 52 would be similar in this case. Even more complex would be pivot-able inserts. Other variations are possible to accomplish such means.

### DETAILED DESCRIPTION—ALTERNATIVE EMBODIMENT

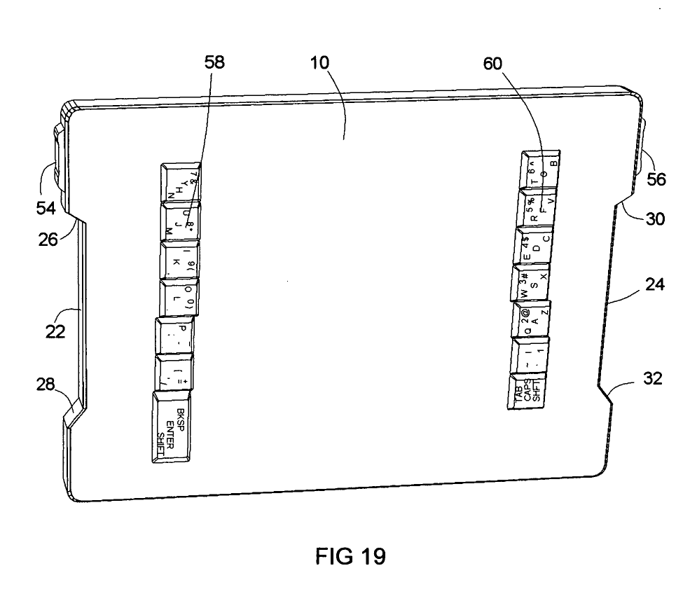

The concept of rapid entry back side keys can be extended to alternative embodiments. For example FIG. 19 shows a single row of keys 58 for the right hand and a single row of keys 60 for the left hand. The user's hands remain on this row, only the index fingers move to access the G and H keys (which also are used to access other letters such as T and Y as explained below), while the pinkie fingers access the keys at the other end (e.g. Tab and Enter.) Selection of the other letters corresponding to the other rows is accomplished by thumb shifters 54, 56. Each thumb shifter 54, 56 would have a home position corresponding to the home row key access (e.g. F and J). In this embodiment, thumb shifter 54 for the right thumb controls the row access for the right hand keys 58. Thumb shifter 56 for the left thumb allows access to the other letters on left hand keys 60. The thumb shifters 54, 56 would slide to one position upwards to allow access to the upper letter row (e.g. the letters Q and U). The thumb shifters 54, 56 would slide up two positions to access the numeral row (e.g. 1 and 7). The thumb shifters could slide up three positions to access the function keys (e.g. F1, F9.) The thumb shifters 54, 56 would slide one position down to access the lower row in a keyboard (e.g. letters C and M). The thumb shifter 54, 56 could slide to a second down position to access the lowest row of keys (e.g. Crtl, Alt, Space keys.) The thumb shifters 54, 56 are shown on the sides of the body 10 of the device, visible from the back side. They would in this case wrap around to the front side to allow simultaneous holding and typing. The natural placement of the thumbs while holding and typing is on the front side near the edges.

### Operation

### Preferred Embodiment

The computer or input device with Back Side Keyboard (BSK) can be used in the same applications as prior art notebook or tablet computers or PDA's. Except that this invention allows rapid entry of data while the user is standing or in motion. This opens up new opportunities for computing and rapid data entry, such as using a computer while on a train, bus, or plane. Or using this invention while on the go, such as during meetings, assemblies, inventory control, or field data entry. As in input device it can be used to collect and/or store information for transmission to a host computer. Or it can be an add-on accessory mounted on the back side of a tablet computer, it can utilize the tablet's input screen as additional virtual input.

Operation of this computer or input device allows rapid data entry in many more situations than in prior art. Because the back side keyboard has similar letter placement as a conventional keyboard, the device is easy to learn and master. Alignment of the keys as described facilitates rapid entry of data. Furthermore, certain letters and numbers, such as B, N, or 6, near the split keyboard 38, 40 boundaries can be redundantly placed on each keyboard half for users who haven't learned to touch type in a standard manner.

Pull computer or input device 10 from storage (in bag, on table, shelf, etc.)

Switch on unit if necessary by the power switch 42.

Hold on to unit by placing hands on side handles 22, 24 under top contours 26, 30. Inserts 50, 52 may be in place, hands would hold on to inserts as if they were handles. Place thumbs along front side edges of unit.

Wrap hands around unit, with fingers resting naturally on home row of back side keyboard 38, 40.

Fingers should naturally rest on home row of keys, due to suitable dimensions of unit and/or fitted insert 50, 52, with suitable shape and size.

Enter data to computer or input device 10 by back side keyboard 38, 40 and front side keys 14, 16, 18, 20.

Confirm data entry by observing display 12 for a computer or host computer for an input device.

Fingers rest normally on home row of keys. Fingers reach for the other rows of keys in a motion similar to a regular keyboard. Fingers reach outward more for the upper rows, while fingers reach inward for lower row of keys. To reach the keys at the end of the rows, for example letters B, N, special entry keys such as CAPS and Enter, one needs to rotate the appropriate hand slightly. Hand rotation is slightly different from what is needed on a conventional keyboard. On a conventional keyboard, the hands are allowed to lift off the keyboard. On this device with the back side keyboard, the hands remain holding the device while rapidly inputting data. Rotation is facilitated by the shape of the handles 22, 24 and contours 26, 28, 30, 32 as shown in FIG. 16. Inserts 50, 52 would also retain these general features to facilitate rotation. The use of a compliant material such as foam will allow inserts 50, 52 (as illustrated for insert 50 in FIG. 15) of a flatter shape to facilitate holding and rotation while inputting data.

If you remove one hand, and the other hand inadvertently presses a back side key from back side keyboard 38, 40, sensor 34 or 36 will prevent unintentional data entry.

In a computer application of this invention, the computer will allow mobile operation, and rapid input of data while the user is standing or in motion. Such a computer can have the functionality as prior art laptop computers and have enhanced functionality of prior art tablet computers. This allows full computer usage while on the go, a big advantage. Utilize conventional computer functions, such as DVD drive 46, wireless networking 47. Utilize auxiliary computer controls 44 as needed.

When finished, perform orderly shutdown or standby of computer or input device. Place BSK computer or input device in storage as needed. The BSK computer can be ready quickly again since there is no folding and unfolding as in a laptop or prior art foldable keyboard. Or the user can keep working at a desk by placing the BSK computer in a suitable cradle to allow continuation of data use with other desktop components such as storage device, regular keyboard, or monitor.

### Operation of Alternative Single Split Row Embodiment

The alternative single split row embodiment minimizes the amount of hand motion and finger reach needed for data entry. Operation is similar to preferred embodiment except that: Thumb rest on row selectors 54, 56 on right, left front edges respectively. Data entry is via back side keyboard 58, 60 and front side keys 14, 16, 18, 20.

The user's hands hold the BSK device 10 in FIG. 19 by handles 22, 24 as in the other embodiments described. Instead of having the user's fingers reaching for other rows of keys, the fingers rest on the single rows 58 and 60. The user selects the letters normally in the other rows (for example in a QWERTY keyboard, the rows other than the home row) by using the thumb sliders 54 and 56. These thumb sliders wrap around to the front side edges of the body 10.

Sliding the appropriate thumb slider 54 or 56 up from its normal resting position selects the row above the home row. Sliding the thumb slider 54 or 56 up one more position selects the second row above the home row. Likewise, sliding the thumb slider 54 or 56 down one position from its normal resting position selects the row below the home row. In operation note that it can be possible for a particular thumb slider 54 or 56 to control either selected back side row 58, 60 or both. With this flexibility it is possible to have only one thumb slider.

The alternative embodiment can utilize front side keys 14, 16, 18, 20 as described for the preferred embodiment or alternative arrangement as also described elsewhere.

Back side letter selection assisted by front row selectors 54, 56 as selected by user's right, left thumbs respectively.

### CONCLUSION, RAMIFICATIONS, AND SCOPE OF INVENTION

The Back Side Keyboard (BSK) invention allows rapid entry of data in a portable computer or input device for mobile users.

While my above description contains many specificities, these should not be construed as limitations on the scope of the invention, but rather as an exemplification of one preferred embodiment thereof. Many other variations are possible.

For example, while the keyboards in the Figs here utilize conventional 1 9mm pitch keys, different shape keys and curved arrangements can be utilized to facilitate easy and rapid data entry. The overall shape of the device can be altered to suit various market needs and industrial design trends. The inclusion and arrangement of keys on either the front or back side can be varied. The size and shape of the handles can be altered to suit design specifics.

Accordingly, the scope of the invention should be determined not by the embodiments illustrated, but by the appended claims and their legal equivalents.

I claim:

1. A hand-holdable device comprising:
a. a plurality of user input keys on back side of said device, and
b. a set of handles and contours to position the user's hands and fingers in appropriate alignment and placement to a set of home keys of said user input keys,
whereby said handles and contours allow hand holding of said device while leaving the user's thumbs and fingers to be free,
whereby said handles and contours maintain overall position of the user's hands even as the user uses said back side input keys to rapidly input data,
whereby a user can hold said device and rapidly input data.

2. The device of claim 1 wherein said back side input keys comprise of a split keyboard on said back side. Whereby the user's left hand fingers accesses one portion of said split keyboard, and the user's right hand fingers access the other portion of said split keyboard,

3. The device of claim 1 wherein a plurality of said home keys have tactile markings for rapid identification and position,

4. The device of claim 1 wherein said back side input keys are arranged to accommodate the natural motion and reach of the user's fingers from said home keys position,

5. The device of claim 1 wherein said back side keys comprise of a split qwerty keyboard, and said home keys consist of characters a, s, d, and f for the left hand and j, k, l, and ; for the right hand. Whereby rapid data entry is accomplished by touch typing on said keyboard,

6. The device of claim 1 wherein said handles and contours maintain overall position of the user's hands relative to said home keys while allowing the hands to slightly rotate to reach individual keys,

7. The device of claim 1 wherein said handles and contours maintain overall position of the user's hands relative to said home keys, even when said device is held and used in a vertical orientation,

8. The device of claim 1 further including inserts for said handles to accommodate for differences in hand size and user preferences,

9. The device of claim 1 further including a set of handle sensors to prevent key strokes unless both hands are in their proper position relative to said handles and contours,

10. The device of claim 1 further including a set of front side input keys, said front side input keys may be of less used keys and control keys,

11. The device of claim 1 further including a set of physical keys and a display on said front side,

12. The device of claim 1 further including an extended display on said front side, a portion of said extended display can act as an arrangement of virtual front input keys as needed,

13. The device of claim 1 further including surface features on said front side to provide a sense of position for an arrangement of front input keys, whereby allowing quick user location of said arrangement of front input keys,

14. The device of claim 1 further including other computer functions such as cursor control, communication, connectivity, drives, and screen input,

15. The device of claim 1 wherein said back side keys comprise of a single row of back side keys for each hand and said front side comprise of shifters to select alternative input characters for each key of said back side keys.

16. A method of rapidly inputting data, comprising:
a. providing a device in which a human operator holds in his/her hands,
b. providing handles and contours on said device to properly position the operator's hands on said device, allowing the operator's fingers to wrap around to the back side of said device
c. providing input keys on said back side whereby the operator's fingers line up on a home set of keys of said input keys,
whereby said handles and contours maintain the proper position of the operator's hands and fingers as the operator rapidly inputs data.

17. A hand-holdable device comprising:
a. a plurality of user input keys on back side of said device, and
b. means for aligning a user's hands to a home set of keys on said back side,
whereby a user can hold said device and rapidly input data

18. The device of claim 17 wherein having means for allowing simultaneous holding of said device and rapid data entry.
